(19) United States
(12) Patent Application Publication
(10) Pub. No.: US 2026/0363085 A1
(43) Pub. Date: Nov. 12, 2026

(54) DIE(S) HAVING MULTIPLE REGIONS WITH DIFFERENT POROSITIES

(71) Applicant: QUALCOMM Incorporated, San Diego, CA (US)

(72) Inventors: Ranadeep DUTTA, Del Mar, CA (US); Jonghae KIM, San Diego, CA (US); Je-Hsiung LAN, San Diego, CA (US)

(21) Appl. No.: 19/204,341

(22) Filed: May 9, 2025

(51) Int. Cl. H10W 42/20; C25D 5/02; C25D 7/12; H10W 40/10; H10W 74/10

(52) U.S. Cl. CPC H10W 42/20; C25D 5/022; C25D 7/12; H10W 40/10; H10W 74/131

(57) ABSTRACT

A package includes an interposer and a first die that is electrically coupled to the interposer and that includes a first region and a second region. The first region includes a thermally conductive material and the second region includes the thermally conductive material. The thermally conductive material of the second region is associated with a second porosity that is greater than a first porosity associated with the thermally conductive material of the first region. The package also includes a second die electrically coupled to the interposer and arranged in a side-by-side configuration with the first die on the interposer. The second region is disposed between the first region of the first die and the second die.

### FIELD

Various features relate to integrated device packages.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In state-of-the-art electronic devices, there is generally an expectation that integrated device packages have a small form factor, a low cost, a tight power budget, and high performance. These various goals are often in conflict. For example, form factors of integrated device packages can be decreased by using chiplets that are interconnected to perform operations of a system-on-chip (SoC). However, if two chiplets are located near each other on a silicon substrate, there may be a thermally conductive path between the two chiplets that can degrade the noise figure of one or both of the chiplets. As an example, a low noise amplifier (LNA) chiplet that is located near a power amplifier (PA) chiplet may experience an increased noise figure due to the thermally conductive path, through a silicon substrate on which both chiplets are disposed, that introduces noise from the PA chiplet to the LNA chiplet. Although the LNA chiplet and the PA chiplet may receive ground from different signal sources, the isolation between the signal sources may not be sufficient to prevent ground bounce between the chiplets. Such ground bounce can degrade the noise figure associated with the LNA chiplet. One solution is to space noise-sensitive chiplets, such as an LNA chiplet, farther from larger noise-generating chiplets, such as the PA chiplet. However, increasing the distance between such chiplets can increase the form factor of a package that includes both noise-sensitive chiplets and noise-generating chiplets.

### SUMMARY

Various features relate to integrated circuit devices and/or packages.

One example provides a package that includes an interposer and a first die that is electrically coupled to the interposer and that includes a first region and a second region. The first region includes a thermally conductive material and the second region includes the thermally conductive material. The thermally conductive material of the second region is associated with a second porosity that is greater than a first porosity associated with the thermally conductive material of the first region. The package also includes a second die electrically coupled to the interposer and arranged in a side-by-side configuration with the first die on the interposer. The second region is disposed between the first region of the first die and the second die.

Another example provides a method of fabrication that includes electrically coupling, to an interposer, a first die that includes a first region and a second region. The first region includes a thermally conductive material and the second region includes the thermally conductive material. The thermally conductive material of the second region is associated with a second porosity that is greater than a first porosity associated with the thermally conductive material of the first region. The method also includes electrically coupling a second die to the interposer in a side-by-side configuration with the first die on the interposer such that the second region of the first die is disposed between the first region of the first die and the second die.

Optional additional aspects are described in the dependent claims.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a cross-sectional profile view of an exemplary package that includes a die having regions with different porosities.

FIG. 1B illustrates a cross-sectional profile view of an exemplary package that includes multiple dies each having regions with different porosities.

FIG. 2 illustrates a cross-sectional profile view of exemplary package that includes multiple dies and an interposer each having regions with different porosities.

FIG. 3 illustrates a cross-sectional profile view of exemplary package that includes multiple dies and an interposer each having regions with different porosities and one or more electromagnetic interference (EMI) shielding structures.

FIG. 4 illustrates an exemplary sequence for fabricating an exemplary package that includes a die having regions with different porosities.

FIG. 5 illustrates an exemplary sequence for fabricating dies having regions with different porosities.

FIG. 6 illustrates an exemplary flow diagram of a method of fabrication for a package that includes a die having regions with different porosities.

FIG. 7 illustrates various electronic devices that may integrate an exemplary package that includes a die having regions with different porosities described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, components and circuitry may be shown in block diagrams in order to avoid obscuring the aspects in unnecessary detail. In other instances, well-known structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

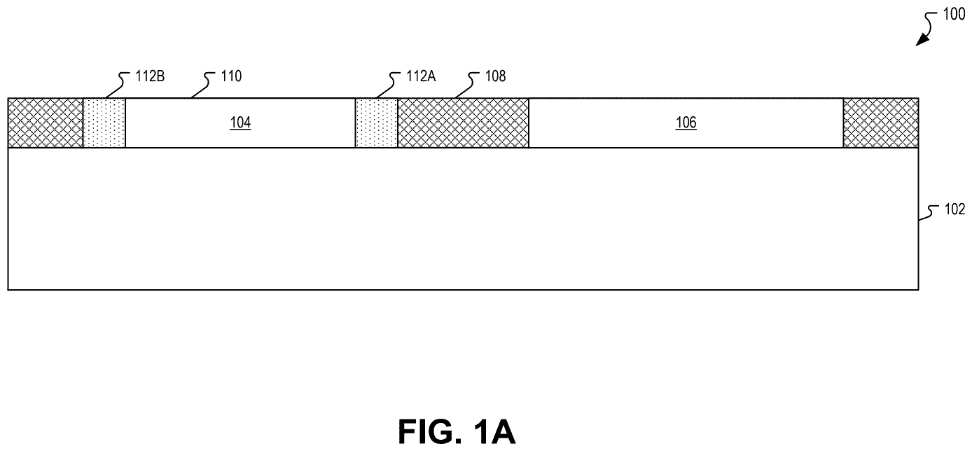

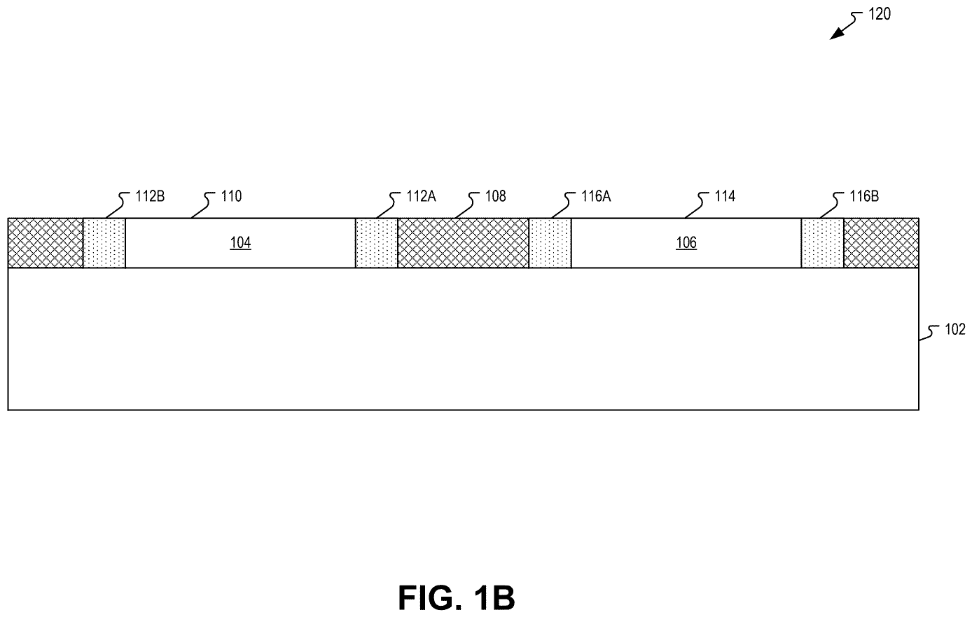

In some drawings in which multiple instances of a particular type of feature are used, different instances are distinguished by addition of a letter to the reference number. In this case, when the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1A, multiple second regions are illustrated and associated with reference numbers 112A and 112B. When referring to a particular one of these second regions, such as a second region 112A, the distinguishing letter “A” is used. However, when referring to any arbitrary one of these second regions or to these second regions as a group, the reference number 112 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. As used herein, a side-by-side configuration or a side-by-side arrangement refers to multiple dies or chiplets that are disposed adjacent to one another (typically in a horizontal direction) on the same substrate or interposer (or interconnected substrates or interposers) instead of being stacked vertically as a three-dimensional (3D) IC device. A 3D IC device refers to an IC device that stacks multiple layers of chips or chiplets on top of each other. Stacked die schemes and chiplet architectures are becoming more common as significant power performance area (PPA) yield enhancements are demonstrated for stacked die and chiplet architecture product lines.

Aspects of the present disclosure are directed to integrated circuit packages that include one or more dies that have regions with different porosities. Some such regions may have larger porosities, and thus reduced thermal conductivity, as compared to other regions of the die(s). In some aspects, a package may include an interposer, a first die that is electrically coupled to the interposer, and a second die that is electrically coupled to the interposer in a side-by-side configuration with the first die. The first die includes a first region and a second region that each include a thermally conductive material, such as silicon, as a non-limiting example. The thermally conductive material of the second region is associated with a second porosity that is greater than a first porosity associated with the thermally conductive material of the first region. The dies are disposed on the interposer such that the second region of the first die that has the greater porosity is disposed between the first region of the first die and the second die, which can reduce or prevent thermal noise generated by the second die from interfering with the first die. In some implementations, the second die includes a third region and a fourth region that include a thermally conductive material, where the thermally conductive material of the fourth region is associated with a fourth porosity that is greater than a third porosity associated with the thermally conductive material of the third region. Additionally, or alternatively, one or more pockets of the interposer may be porosified to form one or more higher porosity regions within the interposer. The disclosed package that includes the die(s) having regions with different porosities provides improved thermal isolation of circuitry, such as dies or chiplets, which reduces a noise figure of the die(s), thereby improving performance of the die(s) and/or enabling multiple dies to be located closer together without degrading performance, which can reduce the size and cost of the package.

### Exemplary Package Including Die(s) Having Regions With Different Porosities

FIG. 1A illustrates a cross-sectional profile view of an exemplary package 100 that includes a die having regions with different porosities. FIG. 1B illustrates a cross-sectional profile view of an exemplary package 120 that includes multiple dies having regions with different porosities.

In the implementation shown in FIG. 1A, the package 100 includes a die 104 (e.g., a first die) and a die 106 (e.g., a second die) that are electrically coupled to an interposer 102. For example, the die 104 and the die 106 may be coupled to a top surface of the interposer 102. The dies 104, 106 may be arranged in a side-by-side configuration on the interposer 102, such that the dies 104, 106 are coupled to the same surface of the interposer 102 and are horizontally adjacent, in the orientation shown in FIG. 1A.

In some embodiments, the interposer 102 is an intermediary layer that is positioned between a package substrate (not shown) and a die (e.g., the die 104 and the die 106). In such embodiments, the interposer 102 can provide conductive connections to enable routing of signals between the dies 104, 106 and the package substrate. The interposer 102 may also provide mechanical/structural support. The interposer 102 can include or be made of silicon, glass, or an organic material (e.g., epoxy or polyimide). In some implementations, the interposer 102 includes a redistribution layer enabling the routing of signals between different chips (e.g., the dies 104, 106) mounted on the

### Interposer 102.

The interposer 102 can include multiple metal layers separated by one or more dielectric layers. The metal layers of the interposer 102 are interconnected with one another at various locations by vias to provide conductive pathways through the thickness of the interposer 102. Additionally, the metal layers may be patterned to define contacts, conductive traces and optionally other features, such as coils of an inductor. In some examples, the interposer 102 can be formed using lamination techniques and materials, or using redistribution layer (RDL) fabrication techniques and materials.

An interposer formed using the lamination techniques includes a metal-prepreg composite stack, in which the dielectric layers include fiber-reinforced polymer layers. A laminate interposer can be formed using conventional package substrate fabrication processes and materials. The dielectric layers can include or correspond to fiber reinforced polymer layers. To illustrate, each dielectric layer can be formed by application (e.g., lay up or lamination) of a pre-preg layer that includes fibers (e.g., strands, mats, tape, etc.) embedded within or coated with a polymer. Epoxy resins are a good choice for the polymer as many epoxies can be partially cured to facilitate handling and later fully cured in-place to facilitate crosslinking and adhesion between adjacent layers. The fibers provide beneficial mechanical characteristics, e.g., resistance to warpage, in a relatively thin substrate. The metal layers can include metal foil layers, often applied as full sheets and subsequently patterned using subtractive techniques (e.g., etching or other removal techniques). As a result, the metal layers tend to be relatively thick (as compared to deposited metal layers), to enable handling during full sheet placement. Additionally, the characteristic line width and line spacing (pitch) of lines of the metal layers is limited due to limitations of the subtractive techniques used to pattern the metal layers and due to clearances and dimensions that enable alignment of conductive vias between the metal layers.

An interposer formed using the RDL fabrication techniques includes a set of redistribution layers, in which the dielectric layers include unreinforced polymer layers. To illustrate, the material of each dielectric layer can be applied as a liquid or gel that is smoothed to form a substantially uniform layer using a spin-coating process or similar smoothing operation. Alternatively, the material of each dielectric layer can be applied as a dry film. In either case, the material includes a polymer (e.g., a polyimide) without fiber reinforcement in order to form a thin, uniform layer. In some cases, the polymer can subsequently be patterned using subtractive techniques, and the patterned polymer can be used (possibly in combination with a patterned photoresist layer) to guide formation of a metal layer. In such cases, the metal layers are formed using additive techniques, such as electroplating, chemical vapor deposition, physical vapor deposition, etc. Using such additive techniques enables formation of metal layers with finer lines than lines of the metal layers of a laminate substrate. In this context, “finer” lines refers to lines that have a smaller characteristic line width, a smaller characteristic pitch, a smaller characteristic line thickness, or a combination thereof, relative to a reference (e.g., lines formed according to the lamination techniques).

Each of the dies 104, 106 can include integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate. The dies 104, 106 may include or correspond to particular IC devices that can be arranged and interconnected as a 2D IC device, a 2.5D IC device, or a 3D IC device. In some implementations, the dies 104, 106 include one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the dies 104, 106. Additionally, or alternatively, the dies 104, 106 may include or be operated as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof. Additionally, or alternatively, the dies 104, 106 may include or correspond to other types of active circuitry. In some implementations, the first die (e.g., the die 104) includes a noise-generating component, such as a power amplifier (PA), and the second die (e.g., the die 106) includes a noise-sensitive component, such as a low-noise amplifier (LNA).

In particular implementations, the dies 104, 106 include one or multiple processors, one or multiple processor cores, or one or more instances of processor circuitry that are interconnected to operate as a processing system, such as an SoC. In implementations in which the dies 104, 106 include or correspond to an SoC, the dies 104, 106 (or processor circuitry thereof) may be ICs that include some or all of the components of a computer system, such as an on-chip CPU, input/output (I/O) interfaces, memory interfaces, and in some implementations, one or more modems or graphic processing units (GPUs). The SoC may be configured to communicate with one or more memories, which in some implementations may be integrated in or correspond to memory dies. Additionally, or alternatively, the dies 104, 106 may include or correspond to multiple chiplets that are respectively configured to operate as processors or processor cores and that, when interconnected, operate as an SoC. In a particular embodiment, the die 104 includes or corresponds to a first chiplet, the die 106 includes or corresponds to a second chiplet, and circuitries of the dies 104, 106 may each include or correspond to respective chiplet circuitry.

In some implementations, the dies 104, 106 are electrically connected to, or integrated with, the interposer 102. For example, each of the dies 104, 106 may be electrically connected (e.g., via one or more contacts or interconnects) to the interposer 102. Additionally, or alternatively, one or more conductors within the interposer 102 may electrically couple one or both of the dies 104, 106 to a component coupled to a bottom side of the interposer 102, such as a package substrate or a printed circuit board, which may provide additional interconnections to other components of the package 100 or a device that includes the package 100. Any of the conductive interconnects and contacts described herein can include, for example, microbumps, conductive pillars, conductive pads (e.g., for pad to pad bonding), or other similar chiplet-to-chiplet interconnect contacts used for 2.5D or 3D chiplet stacking. Additionally, or alternatively, the conductors described herein may include one or more traces, one or more vias, one or more metal lines, or a combination thereof, that are formed from or embedded at least partially within one or more layers of the interposer 102.

In some implementations, the package 100 includes one or more layers or materials between the dies 104, 106 and the interposer 102. For example, one or more oxide layers, such as a potassium oxide layer, may be disposed between the die 104 and the interposer 102 and/or between the die 106 and the interposer 102. Additionally, or alternatively, one or more RDLs may be disposed between the die 104 and the interposer 102 and/or the die 106 and the interposer 102 to provide connections between the dies 104, 106 and conductors or contacts of the interposer 102.

The package 100 also includes an encapsulant 108 that is disposed on the interposer 102 and that at least partially surrounds or encapsulates one or both of the dies 104, 106. The encapsulant 108 may retain the dies 104, 106 in position relative to one another in a side-by-side configuration and/or resist warpage of the package 100. In some implementations, the encapsulant 108 includes or corresponds to a mold compound. Alternatively, the encapsulant 108 may be a different type of compound, such as adhesive or glue, that provides a mechanical connection between at least the dies 104, 106 and the interposer 102.

One or more dies of the package 100 may be formed such that the die(s) include regions having different porosities. Regions of dies having greater porosities than other regions have lower thermal conductivity than regions having lower porosities, and thus dies having regions with greater porosity provide improved thermal isolation between the internal circuitry of the die, which can experience degraded performance due to thermal noise from other components, and other nearby components.

In the particular implementation shown in FIG. 1A, the die 104 includes a first region 110 and one or more second regions 112. The first region 110 and the second regions 112 each include a thermally conductive material, although the thermally conductive material of the second regions 112 is associated with a different porosity than the thermally conductive material of the first region 110. For example, the second regions 112 may undergo a porosification process during fabrication to cause the thermally conductive material of the second regions 112 to be associated with a second porosity that is greater than a first porosity associated with the thermally conductive material of the first region 110. In some implementations, the porosification process includes an oxidation process that oxidizes silicon included in the die 104, such as to form a mask of silicon dioxide (SiO₂) used during the porosification process, and the thermally conductive material included in the die 104 can be oxidized porous silicon. In other implementations, the thermally conductive material of the die 104 may include a different material than silicon that is thermally conductive.

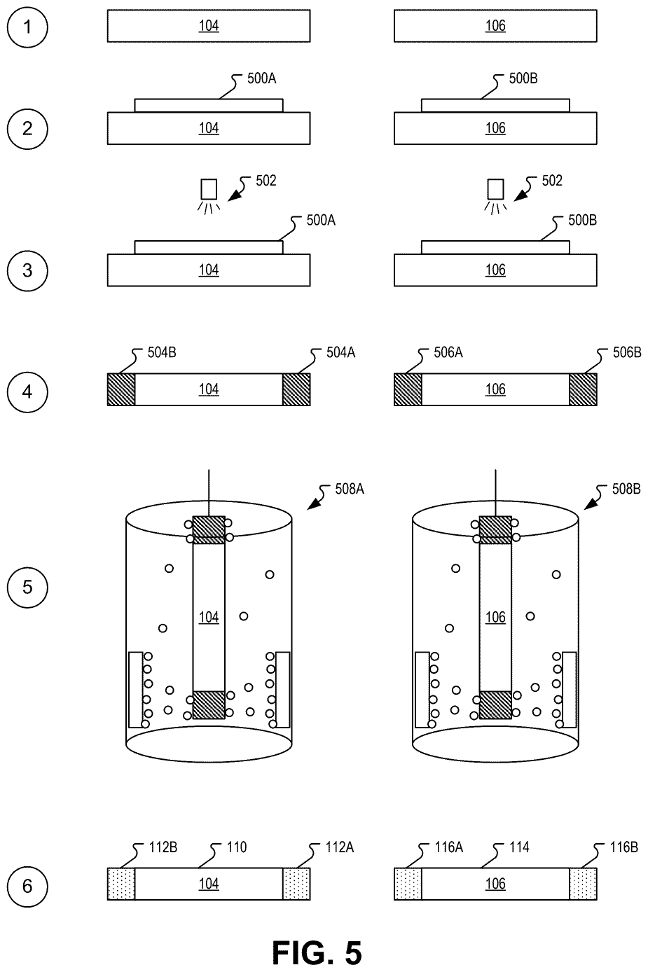

The die 104 may undergo a selective porosification process (e.g., a targeted porosification process) to increase the porosity in scribe line area(s) of the die 104. As used herein, the “scribe line areas” of a die refer to areas along the periphery (e.g., outer edge(s)) of the die, such as where a scribe line or sawing street may be located when the die is part of a wafer during wafer level processing, prior to cutting along the sawing street or scribe line to form the individual die. To selectively porosify the second regions 112 of the die 104, a nitride mask may be applied to the die 104, an electrolyte solution may be applied based on the nitride mask, and the die 104 may undergo an electrolysis process to strip out one or more layers of silicon and/or to create void regions (e.g., pores) within the second regions 112 (e.g., to porosify the second regions 112), which reduces density of silicon within the second regions 112, as further described herein with reference to FIG. 5. As a result, the second regions 112 (e.g., the porous regions/regions having greater porosity) are visually identifiable via transmission electron microscopy (TEM) or scanning electron microscopy (SEM), and the permittivity measured for the second regions 112 is different (e.g., less) than the permittivity measured for the first region 110. In some implementations, the second regions 112 include a second region 112A that is disposed between the die 106 and the first region 110 of the die 104. The second regions 112 also include a second region 112B that is disposed on an opposite side of the first region 110 from the second region 112A. Once the encapsulant 108 is deposited, a portion of the encapsulant 108 is disposed between die 106 and the second region 112A of the die 104. It should be understood that the die 104 including two second regions 112 is provided as an illustrative example. In some other examples, the die 104 includes fewer than two or more than two second regions 112.

Because the second regions 112 include higher porosity silicon than the first region 110 of the die 104, the thermal conductivities associated with the two regions may be different. For example, a first thermal conductivity associated with the first region 110 of the die 104 may be greater than a second thermal conductivity associated with the second regions 112 of the die 104 due to the thermal conductivity of higher porosity silicon being lower than the thermal conductivity of lower porosity silicon. By controlling the second porosity associated with the second regions 112, the second regions 112 can be made thermally non-conductive (or less conductive), electrically non-conductive (or less conductive), or both, which can provide (or increase) thermal isolation of the die 104 from the die 106. Additionally, the regions having greater porosity may have decreased permittivity, which can lower the capacitance associated with the regions, such that the second regions 112 are also low capacitance regions, and thus have a reduced parasitic capacitive effect on signal integrity, as compared to the first region 110.

In some implementations, the first porosity associated with the first region 110 may correspond to the first region 110 having a particular density (e.g., a density of bulk silicon), and the second porosity associated with the second regions 112 may correspond to the second regions 112 having 40% of the particular density. Such lower porosity of the second regions 112 may result in a thermal conductivity associated with the second regions 112 being approximately three orders of magnitude less than a thermal conductivity associated with bulk silicon. In other implementations, the second porosity may correspond to other densities, such as 10% of the particular density, 20% of the particular density, 30% of the particular density, or 50% of the particular density, or the density of the second regions 112 may be within a range, such as 40-50% of the particular density, as non-limiting examples, depending on a target thermal conductivity or thermal noise figure associated with the die 104. Increasing the porosity, and thus reducing the thermal conductivity of the second regions 112 may eliminate (or reduce) the noise generated by the die 104, which in some implementations includes a noise-generating component such as a PA, and which can improve performance of a noise-sensitive component, such as an LNA, included in the die 106. In other implementations, the die 104 can include a noise-sensitive component, and the increased porosity in the second regions 112 can reduce the effects of noise generated by other noise-generating components, such as one included in the die 106.

Although the example shown in FIG. 1A includes a single die (e.g., the die 104) that has regions of different porosities, in other examples, multiple dies may have respective regions of different porosities. An example of such a package 120 that includes multiple dies having regions of different porosities is shown in FIG. 1B. The package 120 includes the interposer 102, the die 104 having the first region 110 and the second regions 112, the die 106 arranged in a side-by-side arrangement with the die 104, and the encapsulant 108 that at least partially surrounds the dies 104, 106. However, unlike in FIG. 1A, in the example shown in FIG. 1B, the die 106 includes a third region 114 and one or more fourth regions 116. The third region 114 and the fourth regions 116 include a same thermally conductive material, such as silicon or porous silicon, which may be the same or different as the thermally conductive material included in the first region 110 and the second regions 112 of the die 104.

Similar to as described above with reference to FIG. 1A, the thermally conductive material of the fourth regions 116 is associated with a fourth porosity that is greater than a third porosity associated with the thermally conductive material of the third region 114. For example, the fourth regions 116 may undergo a porosification process during fabrication to cause the thermally conductive material of the fourth regions 116 to be associated with a fourth porosity that is greater than a third porosity associated with the thermally conductive material of the third region 114. In some implementations, the third porosity corresponds to a particular density, and the fourth porosity corresponds to 40% of the particular density. In some implementations, the porosification process includes an oxidation process of the silicon included in the die 106, and the thermally conductive material included in the die 106 is oxidized porous silicon. In other implementations, the thermally conductive material and the interposer 102 may include a different material than silicon that is thermally conductive, which may include or be different from the thermally conductive material of the die 104.

Similar to as described above for the die 104, the scribe line areas (e.g., the peripheral areas) of the die 106 may be porosified. To illustrate, the fourth regions 116 may include a fourth region 116A that is disposed between the third region 114 of the die 106 and the second region 112A of the die 104. The fourth regions 116 may also include a fourth region 116B that is disposed on an opposite side of the third region 114 from the fourth region 116A. Once the encapsulant 108 is deposited, a portion of the encapsulant 108 is disposed between the fourth region 116A of the die 106 and the second region 112A of the die 104. In other examples, the die 106 includes fewer than two or more than two fourth regions 116. Because the fourth regions 116 include higher porosity silicon than the third region 114 of the die 106, the thermal conductivities associated with the two regions may be different. For example, a third thermal conductivity associated with the third region 114 of the die 106 may be greater than a fourth thermal conductivity associated with the fourth regions 116 of the die 106 due to the thermal conductivity of higher porosity silicon being lower than the thermal conductivity of lower porosity silicon. By controlling the fourth porosity associated with the fourth regions 116, the fourth regions 116 can be made thermally non-conductive (or less thermally conductive), electrically non-conductive (or less electrically conductive), or both, which can provide (or increase) thermal isolation of the die 106 from the die 104. Additionally, the regions having greater porosity may have decreased permittivity, which can lower the capacitance associated with the regions, such that the fourth regions 116 are also low capacitance regions, and thus have a reduced parasitic capacitive effect on signal integrity, as compared to the third region 114.

In a particular implementation, the package 100 and/or the package 120 includes an interposer (e.g., the interposer 102). The package 100 and/or the package 120 also includes a first die (e.g., the die 104) that is electrically coupled to the interposer and that includes a first region (e.g., the first region 110) and a second region (e.g., the second region 112A). The first region includes a thermally conductive material and the second region includes the thermally conductive material. The thermally conductive material of the second region is associated with a second porosity that is greater than a first porosity associated with the thermally conductive material of the first region. The package 100 and/or the package 120 also includes a second die (e.g., the die 106) electrically coupled to the interposer and arranged in a side-by-side configuration with the first die on the interposer. The second region is disposed between the first region of the first die and the second die.

The package 100 and/or the package 120 thus experiences increased thermal isolation (e.g., reduced thermal noise) between the die 104 and the die 106, as compared to other packages in which each die has a substantially uniform porosity. For example, the reduced thermal conductivity of the second regions 112 may reduce (or prevent) the thermal noise caused by the die 104 (if the die 104 includes one or more noise-generating components) from degrading performance of the die 106 and/or reduce (or prevent) thermal noise caused by the die 106 from degrading performance of the die 104 (if the die 104 includes one or more noise-sensitive components). For example, if the die 104 includes an LNA that is susceptible to thermal noise (e.g., due to receiving and recognizing low power signals), and the die 106 includes a PA that typically generates significant heat, the greater porosity of the second regions 112 and/or the fourth regions 116 may prevent the LNA from experiencing thermal noise caused by the PA. For example, reducing the density of the second regions 112 and the fourth regions 116 by 40% (e.g., increasing the porosity) may result in approximately 20 times the thermal isolation between the die 104 and the die 106, due to a reduction in thermal conductivities of three orders of magnitude in the second regions 112 and/or the fourth regions 116.

A technical advantage of the reduction in thermal noise (e.g., the increased thermal isolation) includes improved signal quality experienced by the die 104 and/or the die 106, which improves performance of the die 104 and/or the die 106. To illustrate, a noise figure associated with an LNA that is in a side-by-side configuration with a PA in which both dies have substantially uniform porosity is greater than 2 decibels (dB). However, the noise figure if the dies each include regions of 40% less density (e.g., the second regions 112 and the fourth regions 116) may be less than 1 dB. This reduction in thermal noise can be achieved without significantly increasing the complexity of a fabrication process for the dies 104, 106 and without substantially altering the mechanical stability of the dies 104, 106. Additionally, or alternatively, the improved thermal isolation can “separate” (e.g., isolate) a ground signal of the die 104 from a ground signal of the die 106, which can reduce or prevent ground bounce, thereby improving the performance of the die 104. including separation or isolation of the respective ground signals. Another benefit is that, due to the reduction or prevention of thermal noise, the die 104 and the die 106 may be located closer together than if the die 104 had a substantially uniform porosity, which can decrease the size and cost of the package 100 and/or the package 120.

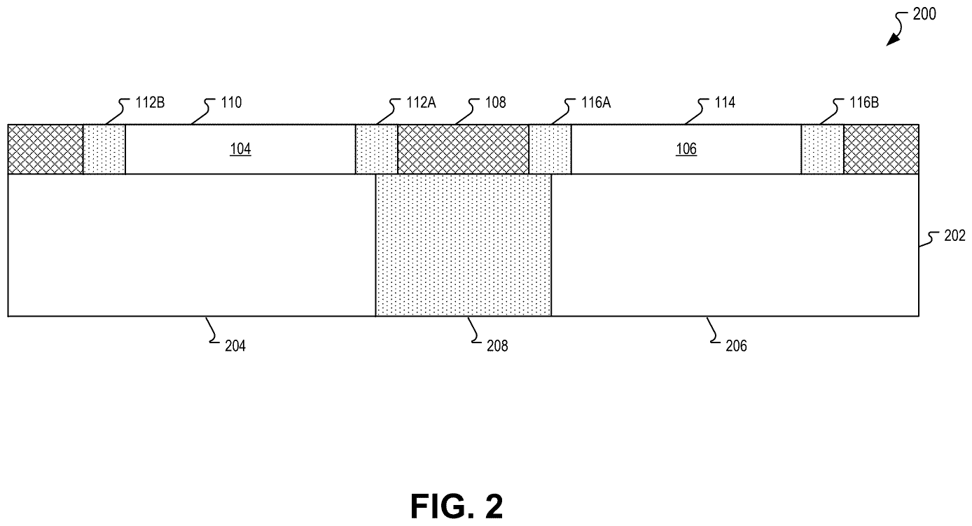

FIG. 2 illustrates a cross-sectional profile view of an exemplary package 200 that includes multiple dies and an interposer each having regions with different porosities. The package 200 of FIG. 2 includes many of the same components and features as are described above with reference to FIGS. 1A-B. Such components and features are physically and operationally the same as described above with reference to FIGS. 1A-B and are labeled in FIG. 2 using the same reference numbers. In some implementations, the package 200 includes all of the same features and components as the package 100 of FIG. 1A or the package 120 of FIG. 1B. To illustrate, although FIG. 2 illustrates the die 106 including the third region 114 and the fourth regions 116, in other embodiments, the die 106 does not have regions of different porosity, as illustrated and described with reference to FIG. 1A. Alternatively, in some other embodiments, the die 104 does not have regions of different porosity.

In the example shown in FIG. 2, the package 200 includes an interposer 202, the die 104, the die 106, and the encapsulant 108. Similar as described above with reference to FIGS. 1A-B, the dies 104, 106 are electrically coupled to the interposer 202 and arranged in a side-by-side arrangement, and the encapsulant 108 is deposited on the interposer 202 and at least partially surrounds the dies 104, 106. The die 104 includes the first region 110 and the second regions 112, as described above with reference to FIG. 1A, and in some implementations, the die 106 includes the third region 114 and the fourth regions 116, as described above with reference to FIG. 1B. In some other implementations, the die 106 does not include regions of different porosities, as described above with reference to FIG. 1A.

In the example shown in FIG. 2, the interposer 202 also includes regions having different porosities. For example, the interposer 202 may undergo a selective porosification process to create one or more target regions having greater porosity than bulk silicon, or another material that is included in the interposer 202. To illustrate, the interposer 202 may include a fifth region 204, a sixth region 206, and a seventh region 208 that is disposed between the fifth region 204 and the sixth region 206. The fifth region 204 includes a thermally conductive material, the sixth region 206 includes the thermally conductive material, and the seventh region 208 includes the thermally conductive material, which may be the same thermally conductive material as the die 104, the die 106, or both. In some implementations, the thermally conductive material of the regions 204-208 is silicon or porous silicon.

Due to a selective porosification process performed on the interposer 202 during fabrication, the thermally conductive material included in the regions 204-206 may be associated with a different porosity than the thermally conductive material included in the seventh region 208. For example, the thermally conductive material of the seventh region 208 may be associated with a seventh porosity that is greater than a fifth porosity associated with the thermally conductive material of the fifth region 204 and a sixth porosity associated with the thermally conductive material of the sixth region 206. The fifth porosity and the sixth porosity may be the same or different, so long as the seventh porosity is greater than each of the fifth porosity and the sixth porosity. Accordingly, the seventh region 208 is associated with a lower thermal conductivity than each of the fifth region 204 and the sixth region 206. Additionally, the regions having greater porosity may have decreased permittivity, which can lower the capacitance associated with the regions, such that the seventh region 208 is also a low capacitance region as compared to the fifth region 204 and the sixth region 206.

In a particular implementation, the fifth porosity and the sixth porosity correspond to a particular density (e.g., a density of bulk silicon), and the seventh porosity corresponds to 40% of the particular density. In other implementations, the seventh porosity corresponds to a value within a range of approximately 20-50% of the particular density. Instead of porosifying the peripheral regions of the interposer 202, pocket(s) of the interposer 202 that are to be located underneath the regions 112A, 116A of the dies 104, 106, respectively, may be porosified. For example, the seventh region 208 may be selected for porosification such that the second region 112A of the die 104 is disposed over at least some of the seventh region 208 of the interposer 202, the fourth region 116A of the die 106 is disposed over at least some of the seventh region 208 of the interposer 202, or both. Additionally, or alternatively, the seventh region 208 of the interposer 202 may be disposed (e.g., horizontally) between the first region 110 of the die 104 and the third region 114 of the die 106. In this manner, placement of the dies 104, 106 may align the porous regions (e.g., the second region 112A and the fourth region 116A) with the seventh region 208 of the interposer 202 to thermally isolate and/or electrically isolate the dies 104, 106 from each other.

Although a single region of higher porosity (e.g., the seventh region 208) is shown in FIG. 2, in other implementations, the interposer 202 may include more than one pocket or region of higher porosity. For example, if more than two dies are electrically coupled to the interposer 202, the interposer 202 may include additional regions of higher porosity disposed between the additional dies. Alternatively, an entirety of the interposer 202 may be porosified such that the thermally conductive material throughout the interposer 202 has the seventh porosity of the seventh region 208, which may be referred to as global porosification of the interposer 202.

The package 200 thus experiences increased thermal isolation (e.g., reduced thermal noise) between the die 104 and the die 106, as compared to the package 100 of FIG. 1A or the package 120 of FIG. 1B. For example, the reduced thermal conductivity of the seventh region 208 may further increase the thermal isolation between the dies 104, 106, thereby reducing (or eliminating) thermal noise from the die 106 that is experienced by the die 104 and/or reducing (or eliminating) the thermal noise from the die 104 that is experienced by the die 106. A technical advantage of the reduction in thermal noise (e.g., the increased thermal isolation) is improved signal quality experienced by the die 104 and/or the die 106, which improves performance of the die 104 and/or the die 106. Additionally, the dies 104, 106 may be located closer together without degrading performance, which enables a reduction in size and cost of the package 200.

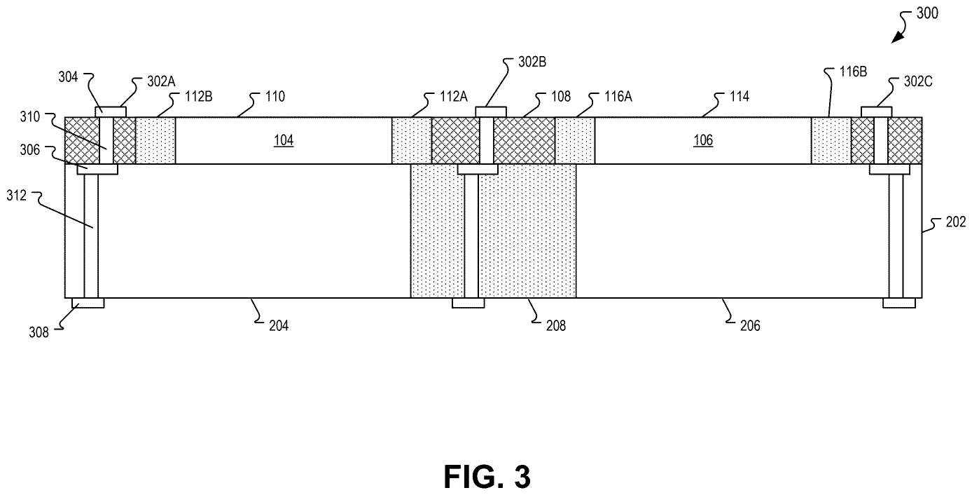

FIG. 3 illustrates a cross-sectional profile view of an exemplary package 300 that includes multiple dies and an interposer each having regions with different porosities and one or more electromagnetic interference (EMI) shielding structures. The package 300 of FIG. 3 includes many of the same components and features as are described above with reference to FIG. 2. Such components and features are physically and operationally the same as described above with reference to FIG. 2 and are labeled in FIG. 3 using the same reference numbers. In some implementations, the package 300 includes all of the same features and components as the package 200 of FIG. 2. To illustrate, although FIG. 3 illustrates the die 106 including the third region 114 and the fourth regions 116, in other embodiments, the die 106 does not have regions of different porosity, as illustrated and described with reference to FIG. 1A. Alternatively, in some other embodiments, the die 104 does not have regions of different porosity.

In the example shown in FIG. 3, the package 300 includes the interposer 202, the die 104, the die 106, and the encapsulant 108. Similar as described above with reference to FIG. 2, the dies 104, 106 are electrically coupled to the interposer 202 and arranged in a side-by-side arrangement, and the encapsulant 108 is deposited on the interposer 202 and at least partially surrounds the dies 104, 106. The die 104 includes the first region 110 and the second regions 112, as described above with reference to FIG. 1A, and in some implementations, the die 106 includes the third region 114 and the fourth regions 116, as described above with reference to FIG. 1B. In some other implementations, the die 106 does not include regions of different porosities, as described above with reference to FIG. 1A. The interposer 202 includes the fifth region 204, the sixth region 206, and the seventh region 208, as described above with reference to FIG. 2.

The package 300 also includes a set of one or more electromagnetic interference (EMI) shielding structures 302 that respectively extend at least partially through the interposer 202 and the encapsulant 108. For example, the EMI shielding structures 302 may include a first EMI shielding structure 302A, a second EMI shielding structure 302B, and a third EMI shielding structure 302C. The first EMI shielding structure 302A may be disposed adjacent to or near the second region 112B of the die 104, the second EMI shielding structure 302B may be disposed between the die 104 and the die 106, and the third EMI shielding structure 302C may be disposed adjacent to or near the fourth region 116B of the die 106. Although three EMI shielding structures 302 are shown in FIG. 3, in other implementations, the package 300 may include fewer than three or more than three EMI shielding structures 302. Additionally, or alternatively, although a single respective EMI shielding structure 302 is shown in each of the various areas of the package 300, in other implementations, multiple EMI shielding structures 302 may be included in the areas associated with the first EMI shielding structure 302A, the second EMI shielding structure 302B, the third EMI shielding structure 302C, or a combination thereof.

Each of the EMI shielding structures 302 may include one or more metal structures, traces, pads, vias, or a combination thereof, to provide EMI shielding to components at least partially surrounded by the EMI shielding structures. For example, the second EMI shielding structure 302B may provide EMI shielding from the die 106 to the die 104, as a non-limiting example. As other examples, the first EMI shielding structure 302A may provide EMI shielding to the die 104 from devices outside of the package 300, and the third EMI shielding structure 302C may provide EMI shielding to the die 106 from devices outside of the package 300.

In a particular implementation, each of the EMI shielding structures 302 includes pads on a pair of opposing surfaces of the package 300, metal lines within the interposer 202, through-mold vias (TMVs) within the encapsulant 108, and through-substrate vias (TSVs) within the interposer 202. As an illustrative example, the first EMI shielding structure 302A includes a pad 304 coupled to a first side (e.g., a top) of the encapsulant 108, a metal line 306 coupled to a second side (e.g., a bottom) of the encapsulant 108 that is opposite to the first side, a TMV 310 that extends between the pad 304 and the metal line 306, a second pad 308 coupled to a bottom side of the interposer 202, and a TSV 312 that extends between the metal line 306 and the second pad 308. The EMI shielding structures 302B-C may include similar pads, metal lines, TMVs, and TSVs. In some other implementations, the EMI shielding structures 302 may include other metal or conductive structures that are configured to provide EMI shielding, such as conductive pillars, conductive cages, or the like.

The package 300 experiences improved thermal isolation and noise reduction as described above with reference to FIG. 2, in addition to improved EMI reduction between the dies 104, 106. For example, by including the EMI shielding structures 302 in the package 300, the EMI shielding structures 302 provide shielding to the dies 104, 106 from EMI produced by the other of the dies 104, 106 (and/or dies outside the package 300), which can decrease noise and improve performance of the dies 104, 106, while also experiencing the increased performance due to the selectively porosified dies 104, 106 and interposer 202. A technical benefit of the EMI shielding structures 302 being included in some regions of greater porosity of the dies 104, 106 and the interposer 202 is to decrease both the thermal noise and the EMI caused by one of the dies 104, 106 to the other of the dies 104, 106, which decreases respective noise figures and thus improves performance of the dies 104, 106. Additionally, reducing or preventing the noise from thermal sources and electromagnetic sources enables the dies 104, 106 to be located more close together, which decreases a size and cost of the package 300.

It should be understood that the package 100, the package 120, the package 200, and/or the package 300 may include additional components, other components, fewer components, or a combination thereof, to support the functionality described herein. As non-limiting examples, the package 100, the package 120, the package 200, and/or the package 300 may include additional IC devices, additional layers, additional dies, additional packages, additional interconnects, additional structures, other components, different components, or a combination thereof, to support the functionality and technical advantages disclosed herein.

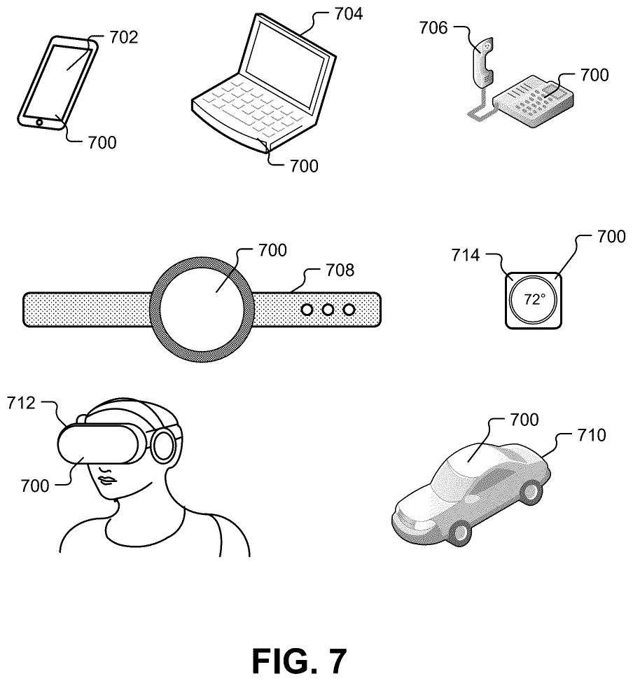

In some implementations, the package 100, the package 120, the package 200, and/or the package 300 can be integrated in a mobile device, a hand-held personal communication system (PCS) unit, a portable data unit, a global positioning system (GPS) enabled device, a navigation device, a set top box, a music player, a video player, an entertainment unit, a virtual reality (VR) device, an augmented reality (AR) device, an extended reality (XR) device, a fixed location data unit, a communications device, a smartphone, a tablet computer, a computer, a wearable device, an Internet of things (IoT) device, a server, a router, a vehicle, or a combination thereof, as described in more detail below with reference to FIG. 7. While FIGS. 1A-3 illustrates examples of packages that that include two dies in a side-by-side arrangement, in other examples, one or more additional dies, integrated devices, packages, or some combination thereof can be present in a side-by-side arrangement and/or a stacked integrated circuit without departing from the scope of the subject disclosure.

Further, the package 100, the package 120, the package 200, and/or the package 300 of FIGS. 1A-3 can be integrated with or included within a wide variety of other components or devices. For example, a device that includes one or more of the package 100, the package 120, the package 200, and/or the package 300 disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the package 100, the package 120, the package 200, and/or the package 300 can operate as any of these components (or a combination of these components) that includes active circuitry.

### Exemplary Sequence for Fabricating a Package That Includes a Die Having Regions With Different Porosities

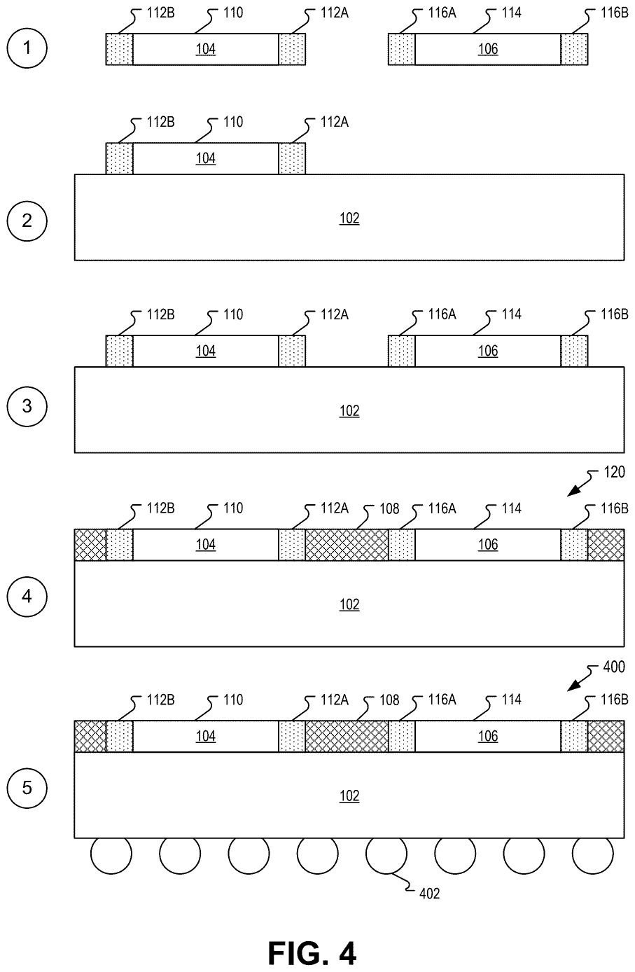

In some implementations, fabricating a package that includes a die having regions with different porosities (e.g., any of the packages 100, 120, 200, or 300) includes several processes. FIG. 4 illustrates an exemplary sequence for fabricating or providing a package that includes a die having regions with different porosities, as described with reference to any of FIGS. 1A-3. In some implementations, the sequence of FIG. 4 may be used to provide (e.g., during fabrication of) one or more of the package 100 of FIG. 1A, the package 120 of FIG. 1B, the package 200 of FIG. 2, or the package 300 of FIG. 3.

It should be noted that the sequence of FIG. 4 may combine one or more stages in order to simplify and/or clarify the sequence for providing or fabricating an integrated device package. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 4. Each of the various stages of the sequence illustrated in FIG. 4 shows a single integrated device package being formed. In other implementations, a plurality of integrated device packages can be formed concurrently.

Stage 1 of FIG. 4 illustrates a state after providing the die 104 and the die 106, each having regions with different porosities. For example, as part of Stage 1, the dies 104, 106 may undergo a selective porosification process to create respective regions in the dies 104, 106 that have different porosities, as further described herein with reference to FIG. 5. In Stage 1, the die 104 includes the first region 110 and the second regions 112, which each include a thermally conductive material. In a particular implementation, the thermally conductive material is silicon. The thermally conductive material of the second regions 112 is associated with a second porosity that is greater than a first porosity associated with the thermally conductive material of the first region 110. As a non-limiting example, the first porosity may correspond to a particular density, and the second porosity may correspond to 40% of the particular density.

Similarly, the die 106 includes the third region 114 and the fourth regions 116, each of which include a thermally conductive material. The thermally conductive material included in the die 106 may be the same or different than the thermally conductive material included in the die 104, and in a particular example, the thermally conductive material is silicon. The thermally conductive material of the fourth regions 116 is associated with a fourth porosity that is greater than a third porosity associated with the thermally conductive material of the third region 114. As a non-limiting example, the third porosity may correspond to a second particular density, and the fourth porosity may correspond to 40% of the second particular density. The second particular density may be the same or different than the particular density associated with the die 104. Although in the example shown in FIG. 4 the die 106 includes the third region 114 and the fourth regions 116, in other implementations, the die 106 may have a substantially uniform porosity, as described with reference to FIG. 1A.

Stage 2 illustrates a state after electrically coupling the die 104 to the interposer 102. For example, as part of Stage 2, the die 104 may be electrically coupled to a first side (e.g., a top) of the interposer 102. In some implementations, the die 104 is electrically coupled to one or more pads or other interconnects on or exposed to a surface of the interposer 102. The die 104 may be coupled to the interposer 102 using flip chip attachment techniques, such as thermal bonding or a reflow solder process. In some implementations, one or more layers (not shown) are disposed between the die 104 and the interposer 102, such as an oxide layer, an RDL, or a combination thereof.

Stage 3 illustrates a state after electrically coupling the die 106 to the interposer 102. For example, as part of Stage 3, the die 106 may be electrically coupled to the first side (e.g., the top) of the interposer 102. In some implementations, the die 106 may be electrically coupled to one or more pads or other interconnects on or exposed to a surface of the interposer 102. The die 106 may be coupled to the interposer 102 using flip chip attachment techniques, such as thermal bonding or a reflow solder process. In some implementations, one or more layers (not shown) are disposed between the die 106 and the interposer 102, such as an oxide layer, an RDL, or a combination thereof.

The die 106 may be coupled to the interposer 102 in a side-by-side configuration with the die 104. Such a configuration may result in higher porosity regions of the dies 104, 106 being closer to each other. For example, the second region 112A of the die 104 may be disposed between the first region 110 of the die 104 and the fourth region 116A of the die 106. As another example, the fourth region 116A of the die 106 may be disposed between the third region 114 of the die 106 and the second region 112A of the die 104. Although the die 106 is described as being coupled to the interposer 102 after the die 104, in other implementations, the die 106 may be coupled to the interposer 102 before the die 104 or concurrently with the die 104.

Stage 4 illustrates a state after depositing the encapsulant 108 on the interposer 102. For example, as part of Stage 4, the encapsulant 108 may be deposited on the interposer 102 to at least partially surround the die 104 and the die 106. In some implementations, the encapsulant 108 includes a mold compound. After being deposited, a portion of the encapsulant 108 is disposed between the second region 112A of the die 104 and the fourth region 116A of the die 106. Formation of the package 120 described with reference to FIG. 1B is complete after Stage 4 of FIG. 4, although additional stages may be performed in some implementations, as further described below, prior to completion of the corresponding package.

Stage 5 illustrates a state after coupling a set of interconnects 402 to the interposer 102. For example, as part of Stage 5, the interconnects 402 may be coupled to a second side (e.g., a bottom) of the interposer 102. The interconnects 402 may include ball grid array (BGA) balls, solder balls, or other solder structures, as non-limiting examples.

Formation of a package 400 (e.g., a package that includes a die having regions of different porosities, and that includes or corresponds to the package 120) is complete after Stage 5 of FIG. 4. However, in some implementations, the sequence described with reference to FIG. 4 can be modified to form the package 100 of FIG. 1A, the package 200 of FIG. 2, or the package 300 of FIG. 3. For example, the die 106 can be provided, at Stage 1, without regions of different porosities to form the package 100 of FIG. 1A after Stage 4. As another example, the interposer 202 having the regions 204-208 can be provided instead of the interposer 102 at Stage 2 to form the package 200 of FIG. 2 after Stage 4. In such an example, electrically coupling the die 104 to the interposer 202 includes disposing at least a portion of the second region 112A of the die 104 over at least a portion of the seventh region 208 of the interposer 202, and electrically coupling the die 106 to the interposer 202 includes disposing at least a portion of the fourth region 116A of the die 106 over at least a portion of the seventh region 208 of the interposer 202. As another example, the sequence can include forming one or more of the EMI shielding structures 302 at least partially through the interposer 102 (or the interposer 202) and the encapsulant 108 to form the package 300 of FIG. 3 after Stage 4.

Although certain Stages are illustrated in FIG. 4 in forming the package 400, other processes can be included in the fabrication of the package 400 without departing from the scope of the subject disclosure. For example, fabricating the package 400 can include forming one or more oxide layers, one or more RDLs, other intermediate layers, one or more metal lines, or a combination thereof, on the interposer 102 prior to coupling the dies 104, 106 to the interposer 102, such that the oxide layer(s), the RDL(s), and/or the other layer(s) are disposed between the die 104 and the interposer 102 and/or between the die 106 and the interposer 102. In this example, fabricating the package 400 may also include forming one or more cavities in the interposer 102 and filling the cavities with metal to form one or more TSVs, in addition to forming one or more metal lines, RDLs, or the like on a bottom surface of the interposer 102. In this example, fabricating the package 400 may also include forming one or more cavities in the encapsulant 108, filling the cavities with metal to form one or more TMVs, and forming one or more metal lines, RDL, or the like on a top surface of the encapsulant 108 to complete formation of the EMI shielding structures 302 of FIG. 3.

### Exemplary Sequence for Fabricating Dies Having Regions With Different Porosities

In some implementations, fabricating dies having regions with different porosities (e.g., any of the dies 104 or 106) includes several processes. FIG. 5 illustrates an exemplary sequence for fabricating or providing dies having regions with different porosities, as described with reference to any of FIGS. 1A-3. In some implementations, the sequence of FIG. 5 may be used to provide (e.g., during fabrication of) one or more of the die 104 of FIGS. 1A-4 or the die 106 of FIGS. 1B-4.

It should be noted that the sequence of FIG. 5 may combine one or more stages in order to simplify and/or clarify the sequence for providing or fabricating one or more dies. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIG. 5. Each of the various stages of the sequence illustrated in FIG. 5 shows multiple dies being formed. In other implementations, a single die may be formed.

Stage 1 of FIG. 5 illustrates a state after providing the die 104 and the die 106. For example, as part of Stage 1, structures to be included in the dies 104, 106 may be formed on a wafer (not shown) as part of one or more wafer-level operations or strip-level operations, and then the corresponding areas may be cut or diced (e.g., during singulation) to form the individual dies 104, 106. During Stage 1, the dies 104, 106 each have a substantially uniform porosity. The die 104 can have the same porosity as the die 106, or the dies 104, 106 may have different substantially uniform porosities.

Stage 2 illustrates a state after masks 500 are applied to the dies 104, 106. For example, as part of Stage 2, a first mask 500A may be applied to a surface (e.g., a top surface) of the die 104 and a second mask 500B may be applied to a surface (e.g., a top surface) of the die 106. In some implementations, the masks 500 include nitride (e.g., the masks 500 are nitride masks). The masks 500 may prevent porosification of regions of the dies 104, 106 that are underneath the masks 500 during a porosification process described in later stage(s). In some implementations, the masks 500 may have one or more dimensions that are smaller than corresponding dimensions of the dies 104, 106 and may be substantially centered on the dies 104, 106 to enable porosification of scribe line areas (e.g., peripheral areas or peripheries) of the dies 104, 106.

Stage 3 illustrates a state during application of an electrolyte solution 502 based on the masks 500. For example, as part of Stage 3, the electrolyte solution 502 may be applied to regions of the dies 104, 106 that are not covered by the masks 500. Although the electrolyte solution 502 is shown in FIG. 5 as being applied as a spray (e.g., a spray coating), in other implementations, the dies 104, 106 may be dipped in the electrolyte solution 502 after application of the masks 500.

Stage 4 illustrates a state after one or more regions of each of the dies 104, 106 are coated in the electrolyte solution 502. For example, as part of Stage 4, the die 104 may include electrolyte-coated regions 504 and the die 106 may include electrolyte-coated regions 506. The electrolyte-coated regions 504, 506 may be scribe line regions or peripheral regions of the dies 104, 106, respectively. For example, the die 104 may include a first electrolyte-coated region 504A and a second electrolyte-coated region 504B along a first edge and a second edge, respectively, of the die 104. Similarly, the die 106 may include a first electrolyte-coated region 506A and a second electrolyte-coated region 506B along a first edge and a second edge, respectively, of the die 106. Although two electrolyte-coated regions are shown in FIG. 5 for each of the dies 104, 106, in other implementations, the die 104, the die 106, or both, may include fewer than two electrolyte-coated regions or more than two electrolyte-coated regions.

Stage 5 illustrates a state during performance of an electrolysis process 508 on the dies 104, 106. For example, as part of Stage 5, a first electrolysis process 508A may be performed on the die 104 to cause the thermally conductive material of the electrolyte-coated regions 504 to be associated with a greater porosity than a remainder of the die 104. Additionally, as part of Stage 5, a second electrolysis process 508B may be performed on the die 106 to cause the thermally conductive material of the electrolyte-coated regions 506 to be associated with a greater porosity than a remainder of the die 106. During the electrolysis process 508, the dies 104, 106 may be placed between an anode and a cathode and a current may be passed between the anode and the cathode to cause electrolysis, which may strip layers of silicon out of the electrolyte-coated regions 504, 506. Stripping the layers of silicon creates pores or voids in the electrolyte-coated regions 504, 506 and thus increases the porosity (e.g., lowers the density) associated with the electrolyte-coated regions 504, 506. The resulting porosity (e.g., density) may be a function of the current that is passed between the anode and the cathode and a duration of the electrolysis process 508, and the current and duration (e.g., parameters of the electrolysis process 508) can be controlled to achieve target porosification for the selected regions of the dies 104, 106. The remainders (e.g., the non-electrolyte-coated regions) of the dies 104, 106 may substantially maintain an original porosity during the electrolysis process 508.

Stage 6 illustrates a state after formation of regions having different porosities within the dies 104, 106. For example, as part of Stage 6, after completion of the electrolysis process 508, and one or more optional cleaning operations to remove any remaining electrolyte solution or buildup from the electrolysis process 508, each of the dies 104, 106 may have regions of differing porosities. For example, the die 104 may include the first region 110 and the second regions 112, and the thermally conductive material of the second regions 112 is associated with a second porosity that is greater than a first porosity associated with the thermally conductive material of the first region 110. As another example, the die 106 may include the third region 114 and the fourth regions 116, and the thermally conductive material of the fourth regions 116 is associated with a fourth porosity that is greater than a third porosity associated with the thermally conductive material of the third region 114. In some implementations, the first porosity of the first region 110 of the die 104 is the same as the third porosity of the die 106 and the second porosity of the second regions 112 of the die 104 is the same as the fourth porosity of the fourth regions 116 of the die 106. In some other implementations, the first porosity is different than the third porosity, the second porosity is different than the fourth porosity, or both.

The regions of greater porosity (e.g., the second regions 112 and the fourth regions 116) may be located along edges of the dies 104, 106 (e.g., the regions may be scribe line regions or peripheral regions), similar to the electrolyte-coated regions 504, 506. For example, the second regions 112 may include or correspond to the electrolyte-coated regions 504 that are located along edges of the die 104. As another example, the fourth regions 116 may include or correspond to the electrolyte-coated regions 506 that are located along the edges of the die 106. The second regions 112 and the fourth regions 116 may be identifiable from the first region 110 and the third region 114, respectively, via TEM or SEM, and/or may have different permittivity values. Additionally, because only target portions of the dies 104, 106 are porosified, the mechanical stability of the dies 104, 106 is not substantially affected. Because the second regions 112 and the fourth regions 116 have greater porosities than the first region 110 and the third region 114, respectively, the dies 104, 106 may be disposed in a side-by-side configuration on an interposer in a manner in which the second regions 112 and the fourth regions 116 provide improved thermal isolation between circuitry of the die 104 and circuitry of the die 106, which can improve a thermal noise figure associated with the dies 104, 106 and thus improve performance of the dies 104, 106 as compared to if the dies 104, 106 had substantially uniform porosity. Formation of the dies 104, 106 (e.g., dies having regions of different porosities) is complete after Stage 6 of FIG. 5.

Although certain Stages are illustrated in FIG. 5 in forming the dies 104, 106, similar processes can be included in the fabrication of other components of an integrated device package having regions of different porosities without departing from the scope of the subject disclosure. For example, fabricating the interposer 202 can include similar operations as described above with reference to Stages 1-6 of FIG. 5 to form the interposer 202 having the regions 204-208. To illustrate, formation of the interposer 202 may include, prior to electrically coupling the die 104 and the die 106 to the interposer 202, applying a mask to a surface (e.g., a top surface) of the seventh region 208 of the interposer 202, similar to as described with reference to Stage 2 of FIG. 5. The formation of the interposer 202 may also include applying an electrolyte solution to the interposer 202 based on the mask, similar to as described with reference to Stages 3 and 4 of FIG. 5. The formation of the interposer 202 may also include performing an electrolysis process on the interposer 202 to cause the thermally conductive material of the seventh region 208 to be associated with the seventh porosity that is different than the porosities of the fifth region 204 and the sixth region 206, similar to as described with reference to Stage 5 of FIG. 5. In such an example, the seventh region 208 has a greater porosity than the fifth region 204 and/or the sixth region 206. Alternatively, one or more different processes may be performed in some other implementations. For example, either the die 104 or the die 106 may not undergo the porosification process shown in FIG. 5, resulting in a single die having regions of different porosities, or more than two dies may undergo the porosification process.

### Exemplary Flow Diagram of a Method for Fabricating a Package that Includes a Die Having Regions with Different Porosities

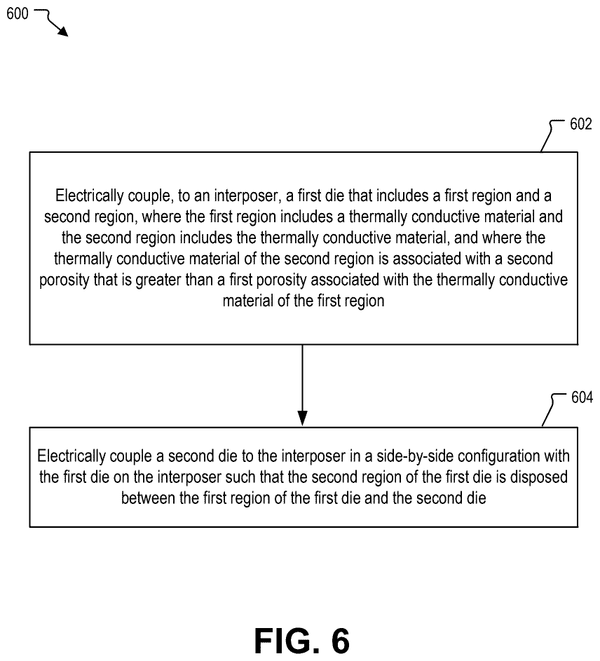

In some implementations, fabricating a package that includes a die having regions with different porosities includes several processes. FIG. 6 illustrates an exemplary flow diagram of a method 600 of fabricating an illustrative package that includes a die having regions with different porosities. In a particular aspect, one or more operations of the method 600 are performed by one or more processors of a fabrication system. In some implementations, operations of the method 600 may be stored as instructions by a non-transitory computer-readable storage medium, and the instructions may be executable by at least one processor to cause the at least one processor to perform operations of the method 600. In some implementations, the method 600 of FIG. 6 may be used to provide or fabricate any of the package 100 of FIG. 1A, the package 120 of FIG. 1B, the package 200 of FIG. 2, the package 300 of FIG. 3, or the package 400 of FIG. 4.

It should be noted that the method 600 of FIG. 6 may combine one or more processes in order to simplify and/or clarify the method for providing or fabricating an integrated device package. In some implementations, the order of the processes may be changed or modified.

The method 600 includes electrically coupling, to an interposer, a first die that includes a first region and a second region, at block 602. The first region includes a thermally conductive material and the second region includes the thermally conductive material, and the thermally conductive material of the second region is associated with a second porosity that is greater than a first porosity associated with the thermally conductive material of the first region. For example, Stage 2 of FIG. 4 illustrates and describes examples of coupling the die 104 to the interposer 102. The first die of the method 600 can include the die 104 of FIGS. 1A-3 that includes the first region 110 and the second regions 112, and the substrate of the method 600 can include the interposer 102 of FIGS. 1A-B or the interposer 202 of FIGS. 2-3. In some implementations, the thermally conductive material is porous silicon. Additionally, or alternatively, the second region of the first die may be associated with approximately 40% of a density of the first region. In some implementations, a first thermal conductivity associated with the first region of the first die is greater than a second thermal conductivity associated with the second region of the first die.

The method 600 includes electrically coupling a second die to the interposer in a side-by-side configuration with the first die on the interposer such that the second region of the first die is disposed between the first region of the first die and the second die, at block 604. For example, Stage 3 of FIG. 4 illustrates and describes examples of electrically coupling the die 106 to the interposer 102. The second die of the method 600 can include the die 106 of FIGS. 1A-3. In some implementations, the first die includes a PA and the second die includes an LNA. Additionally, or alternatively, the first die may include a first chiplet and the second die may include a second chiplet.

In some implementations, the method 600 also includes, prior to electrically coupling the first die to the interposer, applying a mask to a surface of the first die, applying an electrolyte solution to the first die based on the mask, and performing an electrolysis process on the first die to cause the thermally conductive material of the second region to be associated with the second porosity. For example, Stages 2-4 of FIG. 5 illustrate and describe examples of applying the first mask 500A to the die 104 (e.g., to cover the first region 110), applying the electrolyte solution 502 to the die 104 based on the first mask 500A, and performing the first electrolysis process 508A to form the second regions 112 associated with the second porosity that is greater than the first porosity associated with the first region 110.

In some implementations, the second die includes a third region and a fourth region, the third region includes the thermally conductive material and the fourth region includes the thermally conductive material, the thermally conductive material of the fourth region is associated with a fourth porosity that is greater than a third porosity associated with the thermally conductive material of the third region, and the fourth region is disposed between the third region of the second die and the second region of the first die. For example, the third region and the fourth region of the method 600 may include the third region 114 and the fourth regions 116, respectively, of the die 106 of FIGS. 1B-3. In some such implementations, the method 600 also includes, prior to electrically coupling the second die to the interposer, applying a mask to a surface of the second die, applying an electrolyte solution to the second die based on the mask, and performing an electrolysis process on the second die to cause the thermally conductive material of the fourth region to be associated with the fourth porosity. For example, Stages 2-4 of FIG. 5 illustrate and describe examples of applying the second mask 500B to the die 106 (e.g., to cover the third region 114), applying the electrolyte solution 502 to the die 106 based on the second mask 500B, and performing the second electrolysis process 508B to form the fourth regions 116 associated with the fourth porosity that is greater than the third porosity associated with the third region 114.

In some implementations in which the die 106 includes the third region 114 and the fourth regions 116, the interposer includes a fifth region, a sixth region, and a seventh region that is disposed between the fifth region and the sixth region, the fifth region includes the thermally conductive material, the sixth region includes the thermally conductive material, and the seventh region includes the thermally conductive material, and the thermally conductive material of the seventh region is associated with a seventh porosity that is greater than a fifth porosity associated with the thermally conductive material of the fifth region and a sixth porosity associated with the thermally conductive material of the sixth region. For example, the fifth region, the sixth region, and the seventh region of the method 600 may include the fifth region 204, the sixth region 206, and the seventh region 208, respectively, of the interposer 202 of FIGS. 2-3. In some such implementations, the method 600 also includes, prior to electrically coupling the first die to the interposer and prior to electrically coupling the second die to the interposer, applying a mask to a surface of the interposer (e.g., to cover the fifth region 204 and the sixth region 206), applying an electrolyte solution to the interposer based on the mask, and performing an electrolysis process on the interposer to cause the thermally conductive material of the seventh region to be associated with the seventh porosity, similar to as described with reference to FIG. 5 for the dies 104, 106.

In some such implementations in which the substrate includes the fifth region, the sixth region, and the seventh region, electrically coupling the first die to the interposer includes disposing at least a portion of the second region of the first die over at least a portion of the seventh region of the interposer, and electrically coupling the second die to the interposer may include disposing at least a portion of the fourth region of the second die over at least a portion of the seventh region of the interposer. For example, as shown in FIG. 2, a portion of the second region 112A may be disposed over at least a portion of the seventh region 208, and at least a portion of the fourth region 116A may be disposed over at least a portion of the seventh region 208. Additionally, or alternatively, the seventh region of the interposer may be disposed between the first region of the first die and the third region of the second die. For example, as shown in FIG. 2, the seventh region 208 is disposed horizontally between the first region 110 and the third region 114.

In some implementations, the method 600 also includes depositing an encapsulant on the interposer to at least partially surround the first die and the second die, such that a portion of the encapsulant is disposed between the second region of the first die and the second die. For example, Stage 4 of FIG. 4 illustrates and describes examples of depositing the encapsulant 108 on the interposer 102 to at least partially surround the die 104 and the die 106. The encapsulant of the method 600 can include the encapsulant 108 of FIGS. 1A-3, such as a mold compound, as a non-limiting example. In some such implementations, the method 600 also includes forming a set of one or more EMI shielding structures that respectively extend at least partially through the interposer and the encapsulant. For example, the set of one or more EMI shielding structures of the method 600 can include the EMI shielding structures 302 of FIG. 3 that are formed within the interposer 202 and the encapsulant 108. In some such implementations, a first EMI shielding structure of the set of one or more EMI shielding structures includes a pad coupled to a first side of the portion of the encapsulant, a metal line coupled to a second side of the portion of the encapsulant that is opposite to the first side, a TMV that extends between the pad and the metal line, a second pad coupled to a bottom side of the interposer, and a TSV that extends between the metal line and the second pad. For example, the first EMI shielding structure 302A includes the pad 304, the metal line 306, the second pad 308, the TMV 310, and the TSV 312.

### Exemplary Electronic Devices

FIG. 7 illustrates various electronic devices that may include or have integrated within any of the packages 100, 120, 200, 300, or 400 (that include a die having regions of different porosities). For example, a mobile phone device 702, a laptop computer device 704, a fixed location terminal device 706, a wearable device 708, a vehicle 710 (e.g., an automobile or an aerial device), a VR/AR/XR device 712, or an IoT device 714 (e.g., a smart thermostat or another type of IoT device) may include a device 700. The device 700 can include, for example, any of the package 100, the package 120, the package 200, the package 300, the package 400, and/or any other integrated device package that includes a die having regions of different porosities described herein. The devices 702, 704, 706, 708, 712, and 714 and the vehicle 710 illustrated in FIG. 7 are merely exemplary. Other electronic devices may also feature the device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-7 may be rearranged and/or combined into a single component, process, feature or function or embodied in several components, processes, or functions. Additional elements, components, processes, and/or functions may also be added without departing from the disclosure. It should also be noted FIGS. 1A-7 and its corresponding description in the present disclosure is not limited to dies and/or ICs or packages. In some implementations, FIG. 1A-7 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, an integrated device package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately ‘value X’”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the phrase “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. A UBM layer may include a thin film metal layer formed between an IC or metal pillars and solder bumps, such as in a flip chip package. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a package includes: an interposer; a first die that is electrically coupled to the interposer and that includes a first region and a second region, where the first region includes a thermally conductive material and the second region includes the thermally conductive material, and where the thermally conductive material of the second region is associated with a second porosity that is greater than a first porosity associated with the thermally conductive material of the first region; and a second die electrically coupled to the interposer and arranged in a side-by-side configuration with the first die on the interposer, where the second region is disposed between the first region of the first die and the second die.

Example 2 includes the package of Example 1, where the thermally conductive material is porous silicon.

Example 3 includes the package of Example 1 or Example 2, where: the second die includes a third region and a fourth region, the third region includes the thermally conductive material and the fourth region includes the thermally conductive material, the thermally conductive material of the fourth region is associated with a fourth porosity that is greater than a third porosity associated with the thermally conductive material of the third region, and the fourth region is disposed between the third region of the second die and the second region of the first die.

Example 4 includes the package of Example 3, where: the interposer includes a fifth region, a sixth region, and a seventh region that is disposed between the fifth region and the sixth region, the fifth region includes the thermally conductive material, the sixth region includes the thermally conductive material, and the seventh region includes the thermally conductive material, and the thermally conductive material of the seventh region is associated with a seventh porosity that is greater than a fifth porosity associated with the thermally conductive material of the fifth region and a sixth porosity associated with the thermally conductive material of the sixth region.

Example 5 includes the package of Example 4, where: the second region of the first die is disposed over at least some of the seventh region of the interposer, the fourth region of the second die is disposed over at least some of the seventh region of the interposer, or both.

Example 6 includes the package of Example 4 or Example 5, where the seventh region of the interposer is disposed between the first region of the first die and the third region of the second die.

Example 7 includes the package of any of Examples 1 to 6 and further includes: an encapsulant that is disposed on the interposer and that at least partially surrounds the first die and the second die, where a portion of the encapsulant is disposed between the second region of the first die and the second die; and a set of one or more electromagnetic interference (EMI) shielding structures that respectively extend at least partially through the interposer and the encapsulant.

Example 8 includes the package of Example 7, where a first EMI shielding structure of the set of one or more EMI shielding structures includes: a pad coupled to a first side of the portion of the encapsulant; a metal line coupled to a second side of the portion of the encapsulant that is opposite to the first side; a through-mold via (TMV) that extends between the pad and the metal line; a second pad coupled to a bottom side of the interposer; and a through-substrate via (TSV) that extends between the metal line and the second pad.

Example 9 includes the package of any of Examples 1 to 8, where the first die includes a power amplifier (PA), and where the second die includes a low-noise amplifier (LNA).

Example 10 includes the package of any of Examples 1 to 9, where a first thermal conductivity associated with the first region of the first die is greater than a second thermal conductivity associated with the second region of the first die.

Example 11 includes the package of any of Examples 1 to 10, where the second region of the first die is associated with approximately 40% of a density of the first region of the first die.

Example 12 includes the package of any of Examples 1 to 11, where the first die includes a first chiplet, and where the second die includes a second chiplet.

Example 13 includes the package of any of Examples 1 to 12, where the package is integrated within a mobile device, a hand-held personal communication system (PCS) unit, a portable data unit, a global positioning system (GPS) enabled device, a navigation device, a set top box, a music player, a video player, an entertainment unit, a virtual reality (VR) device, an augmented reality (AR) device, an extended reality (XR) device, a fixed location data unit, a communications device, a smartphone, a tablet computer, a computer, a wearable device, an Internet of things (IoT) device, a server, a router, a vehicle, or a combination thereof.

According to Example 14, a method of fabrication includes: electrically coupling, to an interposer, a first die that includes a first region and a second region, where the first region includes a thermally conductive material and the second region includes the thermally conductive material, and where the thermally conductive material of the second region is associated with a second porosity that is greater than a first porosity associated with the thermally conductive material of the first region; and electrically coupling a second die to the interposer in a side-by-side configuration with the first die on the interposer such that the second region of the first die is disposed between the first region of the first die and the second die.

Example 15 includes the method of Example 14 and further includes, prior to said electrically coupling the first die to the interposer: applying a mask to a surface of the first die; applying an electrolyte solution to the first die based on the mask; and performing an electrolysis process on the first die to cause the thermally conductive material of the second region to be associated with the second porosity.

Example 16 includes the method of Example 14 or Example 15, where: the second die includes a third region and a fourth region, the third region includes the thermally conductive material and the fourth region includes the thermally conductive material, the thermally conductive material of the fourth region is associated with a fourth porosity that is greater than a third porosity associated with the thermally conductive material of the third region, and the fourth region is disposed between the third region of the second die and the second region of the first die.

Example 17 includes the method of Example 16 and further includes, prior to said electrically coupling the second die to the interposer: applying a mask to a surface of the second die; applying an electrolyte solution to the second die based on the mask; and performing an electrolysis process on the second die to cause the thermally conductive material of the fourth region to be associated with the fourth porosity.

Example 18 includes the method of any of Examples 15 to 17, where: the interposer includes a fifth region, a sixth region, and a seventh region that is disposed between the fifth region and the sixth region, the fifth region includes the thermally conductive material, the sixth region includes the thermally conductive material, and the seventh region includes the thermally conductive material, and the thermally conductive material of the seventh region is associated with a seventh porosity that is greater than a fifth porosity associated with the thermally conductive material of the fifth region and a sixth porosity associated with the thermally conductive material of the sixth region.

Example 19 includes the method of Example 18 and further includes, prior to said electrically coupling the first die to the interposer and said electrically coupling the second die to the interposer: applying a mask to a surface of the interposer; applying an electrolyte solution to the interposer based on the mask; and performing an electrolysis process on the interposer to cause the thermally conductive material of the seventh region to be associated with the seventh porosity.

Example 20 includes the method of Example 18 or Example 19, where: said electrically coupling the first die to the interposer includes disposing at least a portion of the second region of the first die over at least a portion of the seventh region of the interposer; and said electrically coupling the second die to the interposer includes disposing at least a portion of the fourth region of the second die over at least a portion of the seventh region of the interposer

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A package comprising:
an interposer;
a first die that is electrically coupled to the interposer and that includes a first region and a second region, wherein the first region includes a thermally conductive material and the second region includes the thermally conductive material, and wherein the thermally conductive material of the second region is associated with a second porosity that is greater than a first porosity associated with the thermally conductive material of the first region; and
a second die electrically coupled to the interposer and arranged in a side-by-side configuration with the first die on the interposer,
wherein the second region is disposed between the first region of the first die and the second die.

2. The package of claim 1, wherein the thermally conductive material is porous silicon.

3. The package of claim 1, wherein:
the second die includes a third region and a fourth region,
the third region includes the thermally conductive material and the fourth region includes the thermally conductive material,
the thermally conductive material of the fourth region is associated with a fourth porosity that is greater than a third porosity associated with the thermally conductive material of the third region, and
the fourth region is disposed between the third region of the second die and the second region of the first die.

4. The package of claim 3, further wherein:
the interposer includes a fifth region, a sixth region, and a seventh region that is disposed between the fifth region and the sixth region,
the fifth region includes the thermally conductive material, the sixth region includes the thermally conductive material, and the seventh region includes the thermally conductive material, and
the thermally conductive material of the seventh region is associated with a seventh porosity that is greater than a fifth porosity associated with the thermally conductive material of the fifth region and a sixth porosity associated with the thermally conductive material of the sixth region.

5. The package of claim 4, wherein the second region of the first die is disposed over at least some of the seventh region of the interposer, the fourth region of the second die is disposed over at least some of the seventh region of the interposer, or both.

6. The package of claim 4, wherein the seventh region of the interposer is disposed between the first region of the first die and the third region of the second die.

7. The package of claim 1, further comprising:
an encapsulant that is disposed on the interposer and that at least partially surrounds the first die and the second die, wherein a portion of the encapsulant is disposed between the second region of the first die and the second die; and
a set of one or more electromagnetic interference (EMI) shielding structures that respectively extend at least partially through the interposer and the encapsulant.

8. The package of claim 7, wherein a first EMI shielding structure of the set of one or more EMI shielding structures includes:
a pad coupled to a first side of the portion of the encapsulant;
a metal line coupled to a second side of the portion of the encapsulant that is opposite to the first side;
a through-mold via (TMV) that extends between the pad and the metal line;
a second pad coupled to a bottom side of the interposer; and
a through-substrate via (TSV) that extends between the metal line and the second pad.

9. The package of claim 1, wherein the first die includes a power amplifier (PA), and wherein the second die includes a low-noise amplifier (LNA).

10. The package of claim 1, wherein a first thermal conductivity associated with the first region of the first die is greater than a second thermal conductivity associated with the second region of the first die.

11. The package of claim 1, wherein the second region of the first die is associated with approximately 40% of a density of the first region of the first die.

12. The package of claim 1, wherein the first die includes a first chiplet, and wherein the second die includes a second chiplet.

13. The package of claim 1, wherein the package is integrated within a mobile device, a hand-held personal communication system (PCS) unit, a portable data unit, a global positioning system (GPS) enabled device, a navigation device, a set top box, a music player, a video player, an entertainment unit, a virtual reality (VR) device, an augmented reality (AR) device, an extended reality (XR) device, a fixed location data unit, a communications device, a smartphone, a tablet computer, a computer, a wearable device, an Internet of things (IoT) device, a server, a router, a vehicle, or a combination thereof.

14. A method of fabrication, the method comprising:
electrically coupling, to an interposer, a first die that includes a first region and a second region, wherein the first region includes a thermally conductive material and the second region includes the thermally conductive material, and wherein the thermally conductive material of the second region is associated with a second porosity that is greater than a first porosity associated with the thermally conductive material of the first region; and
electrically coupling a second die to the interposer in a side-by-side configuration with the first die on the interposer such that the second region of the first die is disposed between the first region of the first die and the second die.

15. The method of claim 14, further comprising, prior to said electrically coupling the first die to the interposer:
applying a mask to a surface of the first die;
applying an electrolyte solution to the first die based on the mask; and
performing an electrolysis process on the first die to cause the thermally conductive material of the second region to be associated with the second porosity.

16. The method of claim 14, wherein:
the second die includes a third region and a fourth region,
the third region includes the thermally conductive material and the fourth region includes the thermally conductive material,
the thermally conductive material of the fourth region is associated with a fourth porosity that is greater than a third porosity associated with the thermally conductive material of the third region, and
the fourth region is disposed between the third region of the second die and the second region of the first die.

17. The method of claim 16, further comprising, prior to said electrically coupling the second die to the interposer:
applying a mask to a surface of the second die;
applying an electrolyte solution to the second die based on the mask; and
performing an electrolysis process on the second die to cause the thermally conductive material of the fourth region to be associated with the fourth porosity.

18. The method of claim 16, wherein:
the interposer includes a fifth region, a sixth region, and a seventh region that is disposed between the fifth region and the sixth region,
the fifth region includes the thermally conductive material, the sixth region includes the thermally conductive material, and the seventh region includes the thermally conductive material, and
the thermally conductive material of the seventh region is associated with a seventh porosity that is greater than a fifth porosity associated with the thermally conductive material of the fifth region and a sixth porosity associated with the thermally conductive material of the sixth region.

19. The method of claim 18, further comprising, prior to said electrically coupling the first die to the interposer and said electrically coupling the second die to the interposer:
applying a mask to a surface of the interposer;
applying an electrolyte solution to the interposer based on the mask; and
performing an electrolysis process on the interposer to cause the thermally conductive material of the seventh region to be associated with the seventh porosity.

20. The method of claim 18, wherein:
said electrically coupling the first die to the interposer includes disposing at least a portion of the second region of the first die over at least a portion of the seventh region of the interposer; and
said electrically coupling the second die to the interposer includes disposing at least a portion of the fourth region of the second die over at least a portion of the seventh region of the interposer.
